(19) United States
(12) Patent Application Publication
(10) Pub. No.: US 2026/0329187 A1
(43) Pub. Date: Oct. 22, 2026

(54) SUBSTRATE SUPPORT MEMBER, LITHOGRAPHY APPARATUS, AND ARTICLE MANUFACTURING METHOD

(71) Applicant: CANON KABUSHIKI KAISHA, Tokyo (JP)

(72) Inventors: KAZUNORI NAKAJIMA, Tokyo (JP); SHIGEO KOYA, Tochigi (JP); YUICHIRO MORIKUNI, Tochigi (JP); MIDAI SUZUKI, Tokyo (JP); YUICHIRO OGUCHI, Tokyo (JP)

(21) Appl. No.: 19/645,958

(22) Filed: Apr. 13, 2026

(30) Foreign Application Priority Data
Apr. 21, 2025 (JP) 2025-069895

(51) Int. Cl. G03F 7/00

(52) U.S. Cl. CPC G03F 7/707

(57) ABSTRACT

Provided is a substrate support member for supporting a substrate, the substrate support member includes a base, a plurality of pins provided on an upper surface of the base, and a plurality of partition walls that partitions a space between the upper surface and the substrate supported by the pins. The partition walls are concentrically arranged, the upper surface of the base includes a central region and an outer peripheral region, and a surface included in the central region is lower than a surface included in the outer peripheral region, and a difference between a first radius, which is an inner radius of a first partition wall located innermost in the outer peripheral region among the partition walls, and a second radius, which is a radius of the central region, is not more than 50% of the second radius.

### BACKGROUND

### Field of the Technology

The present disclosure relates to a substrate support member, a lithography apparatus, and an article manufacturing method.

### Description of the Related Art

In a lithography process for manufacturing a semiconductor element, a liquid crystal display element, or the like, an exposure apparatus transfers, via a projection optical system, a pattern formed on an original (mask or reticle) onto a substrate (wafer or glass plate) with a resist or the like applied thereon. Such an exposure apparatus includes a stage that can move while supporting a substrate. The stage holds the substrate by vacuum chucking or the like using a substrate chuck. A pin-chuck type substrate chuck is broadly used as the substrate chuck. In the outer peripheral portion of the upper surface of the pin-chuck type substrate chuck, an annular partition wall (which is called a bank portion or a rim portion) is provided, and a plurality of pin members are evenly arranged in a region inside the annular partition wall. When a substrate is mounted on the plurality of pin members and a decompressed space formed between the substrate and the annular partition wall is vacuum-exhausted, the substrate is held by the substrate chuck.

Warpage of a substrate can have influence on the chucking performance o the substrate. Japanese Patent Laid-Open No. 2011-114238 discusses that the central region of a bottom portion, where a plurality of pins are formed, is formed deeper than an outer peripheral region. By reducing the air resistance of vacuum exhaust in the central region, the chucking force in the outer peripheral portion can be improved, and a substrate with concave warpage can be chucked. However, for a substrate with greater concave warpage, there is a problem that the vacuum exhaust flow rate may be insufficient and the substrate cannot be chucked.

To chuck a warped substrate, the exhaust flow rate may be increased during chucking. However, this can lead to increased apparatus size and complexity.

### SUMMARY

The present disclosure provides a technique advantageous for effectively chucking and holding a substrate with a low exhaust flow rate.

An aspect of the present disclosure provides a substrate support member that supports a substrate, the substrate support member including a base, a plurality of pins provided on an upper surface of the base and configured to support the substrate, and a plurality of partition walls configured to partition a space between the upper surface and the substrate supported by the plurality of pins. The plurality of partition walls are concentrically arranged. The upper surface of the base includes a central region including a center of the upper surface, and an outer peripheral region around the central region. A surface included in the central region is lower than a surface included in the outer peripheral region. A difference between a first radius, which is an inner radius of a first partition wall located innermost in the outer peripheral region, and a second radius, which is a radius of the central region, is not more than 50% of the second radius.

Features of the present disclosure will become apparent from the following description of embodiments with reference to the attached drawings. The following description of embodiments is described by way of example.

### BRIEF DESCRIPTION OF THE DRAWINGS

The accompanying drawings, which are incorporated herein, illustrate embodiments of the present disclosure, and together with the description, serve to explain the principles of the embodiments.

FIG. 1 is a schematic view showing the configuration of a lithography apparatus;

FIG. 2 is a sectional view showing an example of the configuration of a chuck;

FIG. 3 is a sectional view showing an example of the configuration of the chuck; and

FIG. 4 is a sectional view showing an example of the configuration of the chuck.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. For conciseness, in the attached drawings, the same reference numerals are used for the same or similar configurations.

A substrate support member according to the present disclosure can be applied to lithography apparatuses for forming a pattern on a substrate, such as an exposure apparatus and an imprint apparatus, but may be applied to other substrate processing apparatuses such as a processing apparatus and an inspection apparatus. An example in which the substrate support member according to the present disclosure is applied to a lithography apparatus will be described below.

### First Embodiment

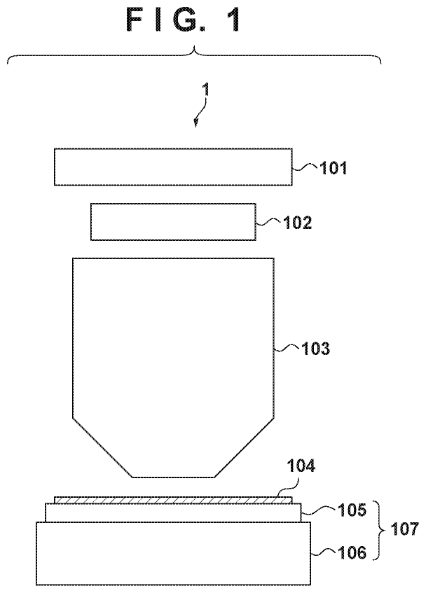

FIG. 1 is a schematic view showing the configuration of a lithography apparatus 1 according to an embodiment. The lithography apparatus 1 is an apparatus that forms (transfers) a pattern onto a substrate. In this embodiment, the lithography apparatus 1 is embodied as an exposure apparatus that forms a pattern on a substrate by exposing the substrate via a projection optical system. However, the lithography apparatus 1 is not limited to the exposure apparatus. For example, the lithography apparatus 1 may be a drawing apparatus that forms a pattern on a substrate by drawing the pattern on the substrate with a charged particle beam (an electron beam, ion beam, or the like) via a charged particle optical system. In addition, the lithography apparatus 1 may be an imprint apparatus that forms a pattern on a substrate by shaping an imprint material on the substrate using a mold.

As shown in FIG. 1, the lithography apparatus 1 includes an illumination optical system 101, an original stage that holds an original 102, a projection optical system 103, and a substrate stage 107 that holds a substrate 104. The substrate 104 can be a wafer or a glass plate.

In the lithography apparatus 1, light from a light source illuminates the original 102 held by the original stage via the illumination optical system 101. The light having passed through the original 102 is applied to the substrate 104 via the projection optical system 103 (that is, an image of the pattern of the original 102 is formed on the substrate 104).

The substrate stage 107 can include a chuck 105 serving as a substrate support member that can move while holding the substrate 104, and a stage main body 106 that supports the chuck 105. The stage main body 106 can include a driving mechanism for moving the substrate 104 in, for example, six axial directions.

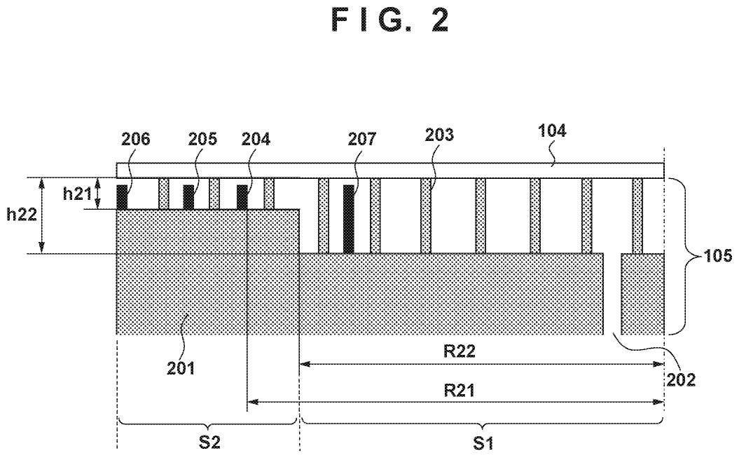

FIG. 2 is a sectional view of the chuck 105 in this embodiment. A base 201 of the chuck 105 is made of a material having excellent thermal conductivity, for example, SiC ceramics. One or more substrate vacuum holes 202, which are through holes extending vertically through the base 201, are formed in the base 201. The one or more substrate vacuum holes 202 are connected to a vacuum source. Chuck vacuum holes for chucking the chuck 105 to the stage main body 106 are formed in the stage main body 106 and connected to a vacuum source.

To convey the substrate 104 onto the chuck 105 or collect the substrate 10 from the chuck 105, lift pins are used to transfer the substrate 104 (pins that chuck the substrate 104 and move vertically relative to the stage main body 106). Therefore, as through holes extending through the base 201, lift pin holes having a larger diameter than the lift pins are also formed in the base 201.

The chuck 105 includes a plurality of pins 203 extending upward from the upper surface of the base 201. The upper surfaces of the plurality of pins 203 constitute a substrate support surface (mounting surface) that contacts the back surface of the substrate 104 and supports the substrate 104. By defining the substrate support surface, the plurality of pins 203 can hold the substrate 104 while maintaining high flatness during vacuum-chucking of the substrate 104. The chuck 105 includes a plurality of partition walls for partitioning a space between the upper surface of the base 201 and the substrate 104 supported by the plurality of pins 203. The plurality of partition walls are provided to make the space between the substrate 104 and the base 201 a decompressed space. In this embodiment, the plurality of partition walls are concentrically arranged.

In this embodiment, the upper surface of the base 201 includes a central region S1 including the center of the upper surface, and an outer peripheral region S2 around the central region S1. The surface included in the central region S1 is lower than the surface included in the outer peripheral region S2.

The plurality of partition walls can include a first partition wall 204, which is located innermost in the outer peripheral region S2 among the plurality of partition walls, a second partition wall 205 outside the first partition wall 204, and a third partition wall 206 outside the second partition wall 205. The plurality of partition walls can include a fourth partition wall 207 arranged in the central region S1. The third partition wall 206 is installed in the outer peripheral portion of the base 201. Therefore, the third partition wall 206 may also be called an outer peripheral partition wall. Since the first partition wall 204, the second partition wall 205, and the fourth partition wall 207 are installed inside the third partition wall 206, the first partition wall 204, the second partition wall 205, and the fourth partition wall 207 may be referred to as intermediate partition walls. In this embodiment, there are three intermediate partition walls including the first partition wall 204, the second partition wall 205, and the fourth partition wall 207, but the number of the intermediate partition walls is not so limited.

Let h21 be the height (length) of the pin 203 from the bottom portion of the outer peripheral region S2, and h22 be the height (length) of the pin 203 from the bottom portion of the central region S1. To define the flat substrate support surface by the plurality of pins 203, the length of the pin 203 formed in the central region S1 is different from the length of the pin 203 formed in the outer peripheral region S2. Here, since the central region S1 is formed deeper than the outer peripheral region S2, h21<h22 holds. In an example, h21 can be 50% or less of h22. Note that in FIG. 2, the pin 203 in the central region is shown in a simple cylindrical shape, but it may have, for example, a two-stage pin shape with a thin upper stage and a thick lower stage.

The third partition wall 206 is formed slightly lower than the plurality of pin 203, so that a certain clearance is provided between the back surface of the substrate 104 and the upper end face of the third partition wall 206. The position of the third partition wall 206 in the horizontal direction is preferably close to the outer periphery (end portion) of the substrate 104. Note that in FIG. 2, the outer diameter of the third partition wall 206 matches the outer diameter of the substrate 104, but it does not necessarily match the outer diameter of the substrate 104. The third partition wall 206 may be arranged slightly (for example, several mm) inside the outer periphery of the substrate 104.

The positions and number of the substrate vacuum holes 202 are not particularly limited. The substrate vacuum holes 202 may be arranged in any number, as long as one or more substrate vacuum holes 202 are arranged inside the third partition wall 206. One or more lift pin holes are arranged inside the third partition wall 206.

The first partition wall 204, the second partition wall 205, the third partition wall 206, and the fourth partition wall 207 are formed slightly lower than the plurality of pins 203, and do not contact the substrate 104. The clearances between the back surface of the substrate 104 and the upper end faces of the first partition wall 204, the second partition wall 205, the third partition wall 206, and the fourth partition wall 207 may all be equal to or different from each other. Here, the inner radius of the first partition wall 204 located innermost in the outer peripheral region S2 is defined as a first radius R21, and the radius of the boundary between the central region S1 and the outer peripheral region S2 (the radius of the central region S1) is defined as a second radius R22. At this time, the first partition wall 204 is arranged so that the difference between the first radius R21 and the second radius R22 is 50% or less of the second radius R22. The difference between the first radius R21 and the second radius R22 is more preferably 30% or less of the second radius R22.

The second radius R22, which is the radius of the central region S1, is preferably within a range of, for example, 30% to 80% of the radius of the substrate 104. The second radius R22 is more preferably 50% or more of the radius of the substrate 104.

In this embodiment, as described above, letting h21 be the height of the pin 203 in the outer peripheral region S2 and h22 be the height of the pin 203 in the central region S1, the central region S1 is formed deeper than the outer peripheral region S2 to satisfy a relationship expressed by h21<h22. In other words, in this embodiment, the height h22 of the pin 203 in the central region S1 is formed larger than the height h21 of the pin 203 in the outer peripheral region S2. This can reduce the resistance of air flowing due to vacuum exhaust as compared to the conventional chuck, thereby increasing the flow rate of vacuum exhaust. In addition, when the relationship expressed by h21<h22 is satisfied, air resistance occurs at the boundary between the central region S1 and the outer peripheral region S2, making it easier to flatten the concavely warped substrate. When the plurality of intermediate partition walls are formed, air resistance occurs above each of the plurality of intermediate partition walls. Accordingly, the concavely warped substrate is chucked from the central portion up to above each of the plurality of intermediate partition walls, making it possible to flatten the substrate. When the substrate is flattened up to above each of the plurality of intermediate partition walls, the residual warpage amount of the substrate decreases. Thus, the warped substrate can be easily chucked even in the region outside the second partition wall 205 which is on the outermost peripheral side among the plurality of intermediate partition walls. When the first radius R21, which is the inner radius of the first partition wall 204, is closer to the second radius R22, which is the radius of the boundary between the central region S1 and the outer peripheral region S2 (the radius of the central region S1), a greater throttling effect can be achieved. By further increasing the air resistance above the first partition wall 204, it becomes easier to flatten the region from the substrate center to the first partition wall 204 of a largely warped substrate. Accordingly, it is possible to provide a substrate support member that can chuck even a warped substrate with a low exhaust flow rate.

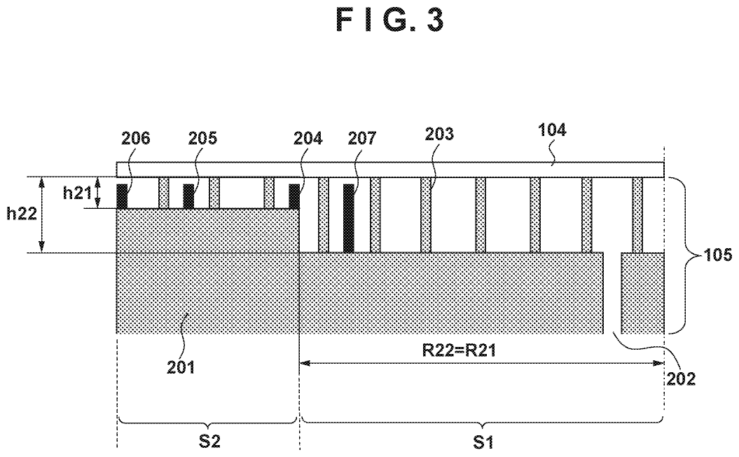

FIG. 3 is a sectional view of the chuck 105 according to the first modification. In FIG. 3, the position of the first partition wall 204 is changed from that in the configuration of the first embodiment (FIG. 2). In FIG. 3, the first partition wall 204 is arranged so that its inner wall is located at the boundary between the central region S1 and the outer peripheral region S2. Hence, the first radius R21, which is the inner radius of the first partition wall 204, is equal to the second radius R22, which is the radius of the boundary between the central region S1 and the outer peripheral region S2 (the radius of the central region S1).

By making R21=R22, an even greater throttling effect may be obtained, and to provide a substrate support member that can chuck a concavely warped substrate with a lower exhaust flow rate.

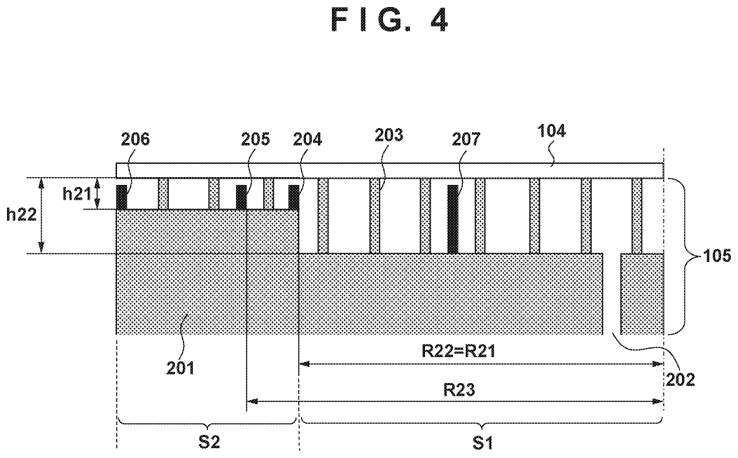

FIG. 4 is a sectional view of the chuck 105 according to the second modification. In FIG. 4, as in FIG. 3, the first partition wall 204 is arranged so that its inner wall is located at the boundary between the central region S1 and the outer peripheral region S2. Hence, the first radius R21, which is the inner radius of the first partition wall 204, is equal to the second radius R22, which is the radius of the boundary between the central region S1 and the outer peripheral region S2 (the radius of the central region S1). The second partition wall 205 is arranged so that the difference between a third radius R23, which is the inner radius of the second partition wall 205, and the first radius R21 (=R22) is 50% or less of R21 (=R22). That is, the second partition wall 205 is arranged so as to satisfy one of Equation (1) or Equation (2):

R23−R21≤0.5R21. . . (1)

R23−R22≤0.5R22. . . (2)

In this case, an even greater throttling effect can be expected above each of the second partition wall 205 and the third partition wall 206. Accordingly, it is possible to provide a substrate support member that can chuck even a concavely warped substrate with a lower exhaust flow rate.

### Embodiment of Article Manufacturing Method

An article manufacturing method according to the present disclosure is suitable to, for example, manufacture an article such as a flat panel display (FPD), a semiconductor device, a sensor, or an optical element. The article manufacturing method according to this embodiment includes a step (formation step) of transferring (forming) the pattern of an original onto a substrate using the above-described lithography apparatus (exposure apparatus, imprint apparatus, drawing apparatus, or the like), and a step (processing step) of processing the substrate with the pattern transferred (formed) thereto in the above step. The article manufacturing method includes other known steps (oxidation, deposition, vapor deposition, doping, planarization, etching, resist peeling, dicing, bonding, and packaging). The article manufacturing method according to this embodiment is advantageous in at least one of the performance, quality, productivity, and production cost of an article as compared to a conventional method.

According to the present disclosure, a technique advantageous for effectively chucking and holding a substrate with a low exhaust flow rate is provided.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2025-069895, filed Apr. 21, 2025 which is hereby incorporated by reference herein in its entirety.

What is claimed is:

1. A substrate support member that supports a substrate, the substrate support member comprising:
a base;
a plurality of pins provided on an upper surface of the base and configured to support the substrate; and
a plurality of partition walls configured to partition a space between the upper surface and the substrate supported by the plurality of pins, wherein:
the plurality of partition walls are concentrically arranged,
the upper surface of the base includes a central region including a center of the upper surface, and an outer peripheral region around the central region,
a surface included in the central region is lower than a surface included i the outer peripheral region, and
a difference between a first radius, which is an inner radius of a first partition wall located innermost in the outer peripheral region, and a second radius, which is a radius of the central region, is not more than 50% of the second radius.

2. The substrate support member according to claim 1, wherein the difference between the first radius and the second radius is not more than 30% of the second radius.

3. The substrate support member according to claim 1, wherein the first radius is equal to the second radius.

4. The substrate support member according to claim 1, wherein
the plurality of partition walls include a second partition wall positioned outside the first partition wall, and
a difference between a third radius, which is an inner radius of the second partition wall, and the second radius is not more than 50% of the second radius.

5. The substrate support member according to claim 4, wherein the difference between the third radius and the second radius is not more than 30% of the second radius.

6. The substrate support member according to claim 1, wherein the second radius is not less than 50% of a radius of the substrate.

7. The substrate support member according to claim 1, wherein a length of a pin in the central region is different from a length of a pin in the outer peripheral region.

8. The substrate support member according to claim 7, wherein the plurality of pins define a flat substrate support surface.

9. The substrate support member according to claim 1, wherein the plurality of partition walls include at least one partition wall formed in the central region.

10. A lithography apparatus comprising:
the substrate support member according to claim 1,
wherein the substrate support member is configured to support the substrate for the lithography apparatus to form a pattern thereon.

11. A method of manufacturing an article, the method comprising:
forming a pattern on the substrate using the lithography apparatus according to claim 10; and
processing the substrate with the pattern formed thereon.

12. A substrate support member comprising:
a base;
a plurality of pins provided on an upper surface of the base, configured to support a substrate; and
a plurality of partition walls configured to partition a space between the upper surface and the substrate supported by the plurality of pins, wherein:
the plurality of partition walls are concentrically arranged,
the upper surface of the base includes a central region and an outer peripheral region,
a surface included in the central region is lower than a surface included i the outer peripheral region.

13. The substrate support member according to claim 12, wherein:
the central region includes a center of the upper surface, and
the outer peripheral region surrounds at least a part of the central region.

14. The substrate support member according to claim 12, further comprising:
a first partition wall located in the outer peripheral region, wherein:
an inner radius of a first partition wall is a first radius, and
a radius of the central region is a second radius.

15. The substrate support member according to claim 14, wherein a difference between the first radius and the second radius is not more than 50% of the second radius.

16. The substrate support member according to claim 14, wherein the first radius is equal to the second radius.

17. The substrate support member according to claim 14, further comprising:
a second partition wall, wherein:
an inner radius of the second partition wall is a third radius,
the second partition wall is positioned outside the first partition wall, and
a difference between the third radius and the second radius is not more than 50% of the second radius.
